(19) United States
(12) Patent Application Publication
(10) Pub. No.: US 2006/0273422 A1
(43) Pub. Date: Dec. 7, 2006

(54) SWITCHING ELEMENT FOR CHARACTERISTIC INSPECTION, AND CHARACTERISTIC INSPECTION METHOD

(75) Inventors: Atsushi ENDO, Tokyo (JP); Takumi NAKAHATA, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Chiyoda-ku (JP)

(21) Appl. No.: 11/276,339

(22) Filed: Feb. 24, 2006

(30) Foreign Application Priority Data
Jun. 2, 2005 (JP) 2005-162375

(51) Int. Cl. H01L 31/00

(52) U.S. Cl. 257/444

(57) ABSTRACT

A thin film transistor for characteristic inspection has a source, a gate and a drain connected to electrode terminals, namely to a source terminal, a gate terminal and a drain terminal, respectively. The electrode terminals are connected to a potential uniformalizing terminal via potential uniformalizing wiring in order to uniform the potentials of the electrode terminals. When conducting a characteristic inspection, a voltage is applied across the electrode terminals and the potential uniformalizing terminal to melt the potential uniformalizing wiring.

### BACKGROUND OF THE INVENTION

1. Field of the Invention

This invention relates to switching elements for characteristic inspection used in a liquid crystal display device and the like, and characteristic inspection methods using the switching elements for characteristic inspection.

2. Description of the Background Art

In a conventional liquid crystal display panel (substrate for liquid crystal display), a transistor for characteristic inspection is formed of a thin film transistor, and each inspection terminal of a source, a drain and a gate thereof is surrounded by a conductive material that is connected to peripheral common wiring.

A drain lead electrode, a gate lead electrode and a source lead electrode thereof are electrically connected to local common wiring that is electrically connected to the peripheral common wiring. The drain and gate thereof are electrically connected to each other.

In addition, the source, the drain and the gate and part of the drain lead electrode, part of the gate lead electrode and part of the source lead electrode thereof are provided within a seal defining liquid crystal of the liquid crystal display panel (see Japanese Patent Application Laid-Open No. 7-56192 (1995), for example).

At the time of characteristic inspection of the transistor for characteristic inspection, wiring is mechanically cut between the drain lead electrode, the source lead electrode, the gate lead electrode and the local common wiring.

However, the thin film transistor for characteristic inspection and the characteristic inspection method using the thin film transistor for characteristic inspection according to the prior art present the following problems:

First, a plurality of thin film transistors for characteristic inspection are arranged on the periphery of an image display area of the liquid crystal display panel, and the peripheral common wiring to be electrically connected to the thin film transistors for characteristic inspection is formed.

This results in the need to connect the thin film transistors for characteristic inspection to the peripheral common wiring, which places restrictions on the arrangement position of the thin film transistors on the liquid crystal display panel.

Also, because the thin film transistors for characteristic inspection are arranged on the periphery of the image display area and cannot be arranged within the image display area, the characteristics of the image display area cannot be inspected.

Moreover, a non-image display area is required for arranging the peripheral common wiring and the like on the periphery of the image display area. This causes an increase in frame area of the liquid crystal display panel, resulting in a decrease in effective frame rate of a compact liquid crystal display panel.

Furthermore, the peripheral common wiring, which is formed to surround the image display area and thus increases in length, tends to have a defect. A defect in the peripheral common wiring will easily cause damage resulting from static electricity and the like to the thin film transistors. This makes it difficult to conduct proper characteristic inspections of the thin film transistors for characteristic inspection.

Second, the wiring is mechanically cut between the drain lead electrode, the source lead electrode and the gate lead electrode of the thin film transistor and the peripheral common wiring in the prior art.

A processing device such as a glass substrate cutting device or a laser irradiation device is thus required for the mechanical cutting of the wiring.

The cutting of the wiring by a glass substrate cutting device or a laser irradiation device makes it difficult to uniform the cut portions. Consequently, a contact abnormality occurs easily between an inspection needle (probe) of an inspection device of the thin film transistor for characteristic inspection and the wiring.

Further in the prior art, the drain lead electrode, the source lead electrode and the gate lead electrode of the thin film transistor for characteristic inspection formed on a glass substrate make direct contact with the probe of the characteristic inspection device.

Consequently, a contact abnormality due to a difference in thermal expansion and the like occurs easily during a low-temperature continuous performance test, or a high-temperature continuous performance test.

It is required that external input/output devices be connected when conducting a characteristic inspection, the external input/output devices including a signal input/output device for inputting and outputting a signal in order to drive a switching element for characteristic inspection, a power supply IC, and the like.

However, terminals for connecting the external input/output devices are not provided in the prior art, which makes it difficult to conduct a characteristic inspection after connecting the external input/output devices.

Moreover, static electricity is produced when connecting the external input/output devices. It is therefore necessary to prevent damage resulting from static electricity produced when connecting the external input/output devices in order to make accurate measurements on the switching element.

### SUMMARY OF THE INVENTION

It is an object of this invention to provide a switching element for characteristic inspection of which a characteristic inspection can be conducted accurately, while placing no restrictions on the arrangement position of the switching element on a liquid crystal display panel, and preventing damage resulting from static electricity which is produced when manufacturing and handling the switching element.

It is also an object of this invention to provide a switching element for characteristic inspection capable of cutting wiring easily without having to use a cutting device.

It is yet another object of this invention to provide a switching element for characteristic inspection of which a characteristic inspection can be conducted accurately, while preventing static electricity when connecting an external input/output device.

In a first aspect of this invention, a switching element for characteristic inspection includes a plurality of electrode terminals, and a potential uniformalizing terminal connected to the plurality of electrode terminals via wiring.

The plurality of electrode terminals are connected to the potential uniformalizing terminal, to become equal in potential. This prevents damage to the switching element resulting from static electricity which is produced when handling the switching element, such as when packaging. Therefore, an accurate characteristic inspection of the thin film transistor can be conducted with a high yield.

In addition, with the potential uniformalizing terminal being provided for each switching element for characteristic inspection, no restrictions are placed on the arrangement position of the switching elements for characteristic inspection when formed on the substrate for liquid crystal display.

In a second aspect of this invention, a characteristic inspection method using a switching element for characteristic inspection that includes a plurality of electrode terminals and a potential uniformalizing terminal connected to the plurality of electrode terminals via wiring includes the steps of: (a) preparing the switching element for characteristic inspection; (b) cutting the wiring; and (c) conducting a characteristic inspection of the switching element for characteristic inspection by using the electrode terminals after the step (b).

The wiring can be cut after packaging. This prevents damage to the switching element for characteristic inspection resulting from static electricity which is produced at the time of packaging. Therefore, an accurate characteristic inspection of the switching element for characteristic inspection can be conducted with a high yield.

In a third aspect of this invention, a characteristic inspection method using a switching element for characteristic inspection that includes a plurality of electrode terminals, a potential uniformalizing terminal connected to the plurality of electrode terminals via wiring, and an external input/output terminal connected to each of the electrode terminals includes the steps of: (a) preparing the switching element for characteristic inspection; (b) connecting an external input/output device to the external input/output terminal; (c) cutting the wiring after the step (b); and (d) conducting a characteristic inspection of the switching element for characteristic inspection by using the electrode terminals after the step (c).

Performance evaluations of the switching element for characteristic inspection can be conducted accurately while preventing damage resulting from static electricity which is produced when connecting the external input/output device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating the structure of a switching element for characteristic inspection according to a first preferred embodiment of this invention;

FIG. 2 is a circuit diagram illustrating the structure of a switching element for characteristic inspection according to a second preferred embodiment of this invention; and

FIG. 3 is a circuit diagram illustrating the structure of a switching element for characteristic inspection according to a third preferred embodiment of this invention.

### DESCRIPTION OF THE PREFERRED EMBODIMENTS

### First Preferred Embodiment

<A. Structure>

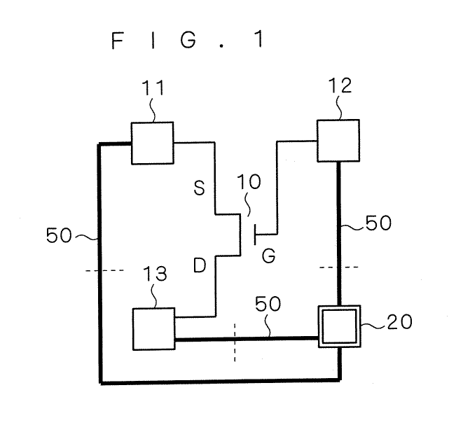

FIG. 1 is a circuit diagram illustrating the structure of a switching element for characteristic inspection according to a first preferred embodiment of this invention. By way of example, a thin film transistor 10 is used as the switching element for characteristic inspection (hereafter sometimes referred to simply as a “switching element”) in this preferred embodiment.

The thin film transistor 10 is arranged on an insulating substrate such as a glass substrate, or on a substrate for liquid crystal display composed of an insulating film such as an organic film.

A switching element for image display (thin film transistor for image display) is formed in an image display area on the substrate for liquid crystal display. The thin film transistor 10 is arranged on the periphery of the image display area.

The thin film transistor 10 has a source S, a gate G and a drain D connected to electrode terminals, namely to a source terminal 11, a gate terminal 12 and a drain terminal 13, respectively.

The source terminal 11, the gate terminal 12 and the drain terminal 13 are connected to a potential uniformalizing terminal 20 uniformalizing (equalizing) the potentials of these terminals via potential uniformalizing wiring (wiring) 50.

The potential uniformalizing terminal 20 is also formed on the substrate for liquid crystal display, and is arranged near the electrode terminals. Namely, the potential uniformalizing terminal 20 is arranged adjacently to the source terminal 11, the gate terminal 12 and the drain terminal 13 in order to be connected to these terminals via the potential uniformalizing wiring 50. More specifically, it is desirable that the potential uniformalizing terminal 20 be arranged to have a distance of 5 μm of more and 1000 μm or less from its adjacent terminal, or the gate terminal 12, for example.

Like the wiring connecting the source S of the thin film transistor 10 and the source terminal 11, the potential uniformalizing wiring 50 is made of materials of low resistance and low melting point when compared to such materials as conductive organic materials or ITO. Namely, the potential uniformalizing wiring 50 is metallic wiring made of metallic materials of low resistance and low melting point such as Al, Mo and Ni.

The potential uniformalizing wiring 50 has a wiring width of 1 to 100 μm to melt easily and reliably upon application of a voltage of 5 to 100 V.

Alternatively, a portion of the potential uniformalizing wiring 50 may be narrower than the other portions of the potential uniformalizing wiring 50. For example, a portion of the potential uniformalizing wiring 50 may be set to 1 to 5 μm in wiring width with the other portions being 10 μm.

That allows a melting position in the wiring by electrical stress to be identified. In the FIG. 1 example, the wiring is formed narrow in portions marked with dashed lines, to melt in those portions.

While a structure has been described in which the switching element for image display is formed in the image display area on the substrate for liquid crystal display, the thin film transistor 10 according to this preferred embodiment, which requires no peripheral common wiring or the like, may be used singly as well.

Therefore, the thin film transistor 10 may be arranged, using a substrate for liquid crystal display in which a switching element for image display is not formed in an image display area, in an image display area or on the periphery thereof. Such arrangement has been unattainable in a conventional switching element for characteristic inspection.

<B. Inspection Method>

A characteristic inspection method using the thin film transistor 10 according to the first preferred embodiment will now be described.

First, the thin film transistor 10 formed on the periphery of the image display area is prepared.

Next, the potential uniformalizing wiring 50 is cut. More specifically, a voltage is applied across the potential uniformalizing terminal 20 and the source terminal 11, across the potential uniformalizing terminal 20 and the gate terminal 12, and across the potential uniformalizing terminal 20 and the drain terminal 13 of the thin film transistor 10. The potential uniformalizing wiring 50 thus melts by electrical stress at the portions marked with dashed lines in FIG. 1.

As a result, the source terminal 11, the gate terminal 12 and the drain terminal 13 are not uniformed in potential, which allows voltages of different magnitudes to be applied to these terminals. Then, desired electric characteristics of the thin film transistor 10 are measured to conduct performance evaluations of the thin film transistor 10.

When using a single thin film transistor 10 (a specific example of the use will be described later), a step of packaging the thin film transistor 10 may be added. The “packaging” as used herein is employed to mean fixing a chip on which the thin film transistor 10 is formed inside a package made of ceramic and the like. The packaging causes less damage to the thin film transistor 10, which allows an inspection as described later to be conducted easily.

The package includes a plurality of terminals that make contact with and are electrically connected to the respective electrode terminals of the thin film transistor 10 inside the package.

After that, the terminals provided in the package are used to apply a voltage across the potential uniformalizing terminal 20 and the source terminal 11, across the potential uniformalizing terminal 20 and the gate terminal 12, and across the potential uniformalizing terminal 20 and the drain terminal 13. The potential uniformalizing wiring 50 thus melts by electrical stress at the portions marked with dashed lines in FIG. 1.

The single thin film transistor 10 having been packaged will be protected from the external environment, and thus will be measured more safely.

<C. Effect>

In the switching element for characteristic inspection according to the first preferred embodiment, the plurality of electrode terminals such as the gate terminal 12 are all connected to the potential uniformalizing terminal 20 via the potential uniformalizing wiring 50.

With all of the plurality of electrode terminals being equal in potential, damage can be prevented resulting from static electricity and the like which is produced when handling the switching element, such as when fixing into a package.

Therefore, an accurate characteristic inspection of the thin film transistor 10 can be conducted with a high yield.

In the switching element for characteristic inspection according to this preferred embodiment, a portion of the potential uniformalizing wiring 50 is formed narrower than the other portions of the potential uniformalizing wiring 50.

Therefore, the potential uniformalizing wiring 50 can melt easily upon application of electrical stress without having to use a particular device. Further, the melting positions in the potential uniformalizing wiring 50 can be identified.

In the switching element for characteristic inspection according to this preferred embodiment, the potential uniformalizing wiring 50 is made of materials that are typically used in forming a thin film transistor. Used as an example are metallic materials made of Al and Mo, which are materials of low resistance and low melting point, or formed of an alloy basically made of Al and Mo.

Therefore, the potential uniformalizing wiring 50 can melt easily upon application of electrical stress.

Unlike ITO or organic conductive films, the metallic materials such as Al are typically used materials in a semiconductor device. Thus, a fine wiring pattern of the potential uniformalizing wiring 50 can be easily formed by a fine patterning technique.

Also, the thin film transistor 10 can be manufactured in accordance with the manufacturing steps of a typical thin film transistor without having to use a particular manufacturing step or device. The thin film transistor 10 can therefore be manufactured on the substrate for liquid crystal display simultaneously with the manufacture of the switching element for image display without having to add a particular step.

Further, with the potential uniformalizing terminal 20 being arranged on the substrate for liquid crystal display and near the thin film transistor 10, an area taken up by the potential uniformalizing wiring 50 can be reduced. The reduction in wiring length of the potential uniformalizing wiring 50 suppresses the occurrence of defects.

Furthermore, with the potential uniformalizing terminal 20 being provided for each thin film transistor 10, the thin film transistor 10 can be used singly. No restrictions are placed on the arrangement position of the singly used thin film transistor 10 on the substrate for liquid crystal display.

The single thin film transistor 10 cannot be formed in the image display area on the substrate for liquid crystal display to conduct a characteristic inspection.

Nevertheless, with no restrictions being placed on the arrangement position thereof, the single thin film transistor 10 can be formed in the same step as the switching element for image display in a position corresponding to an image display area on a substrate for liquid crystal display, by preparing the substrate in which a switching element for image display or the like is not formed.

Consequently, the characteristics of the switching element for image display formed in the image display area can be indirectly evaluated using the single thin film transistor 10.

In the characteristic inspection method of the switching element for characteristic inspection according to this preferred embodiment, the potential uniformalizing wiring 50 melts after packaging. This prevents damage to the switching element resulting from static electricity which is produced at the time of packaging. Therefore, an accurate characteristic inspection of the thin film transistor 10 can be conducted with a high yield.

Also, because the potential uniformalizing wiring 50 melts by electrical stress, a characteristic inspection can be easily conducted without having to use a particular device to cut the wiring 50.

Moreover, the thin film transistor 10 according to this preferred embodiment requires no particular material or step, and can therefore be formed simultaneously with the image display area and the like on the liquid crystal display panel without having to add a manufacturing step.

### Second Preferred Embodiment

<A. Structure>

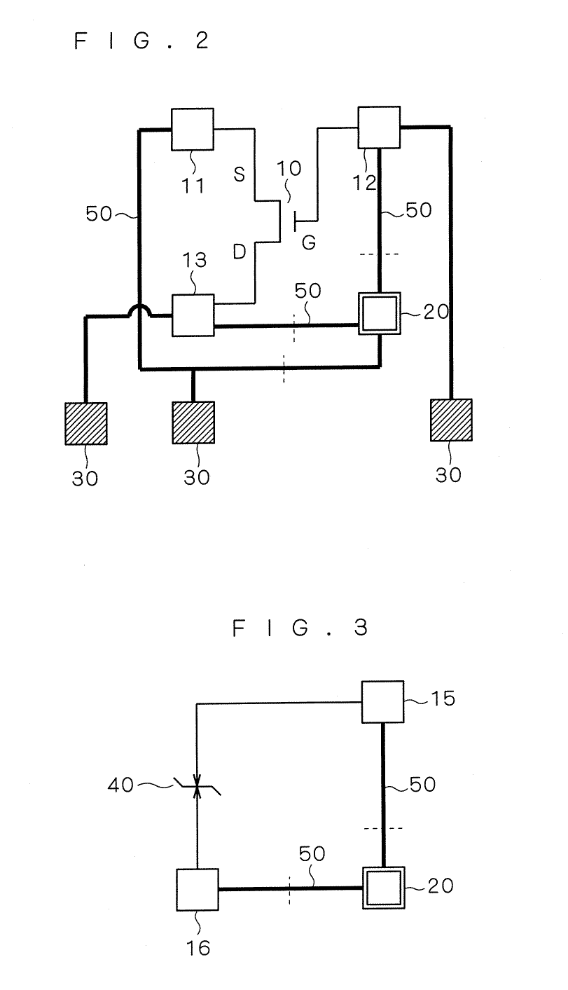

FIG. 2 is a circuit diagram illustrating the structure of a switching element according to a second preferred embodiment of this invention.

This switching element is equivalent to the switching element according to the first preferred embodiment that further includes a plurality of external input/output terminals 30.

Each of the external input/output terminals 30 is connected to the source terminal 11, the gate terminal 12 and the drain terminal 13, respectively.

The other features are the same as those in the first preferred embodiment, with identical features having the same signs to omit redundant descriptions.

<B. Inspection Method>

First, the thin film transistor 10 including the potential uniformalizing terminal 20, the external input/output terminals 30 and the like is prepared.

Next, external input/output devices (not shown) are connected to the respectively corresponding external input/output terminals 30.

The external input/output devices as used herein are employed to mean a power supply IC formed on a flexible substrate such as polyimide films for driving the thin film transistor 10, a signal input/out device, and the like.

Then, a voltage is applied across the potential uniformalizing terminal 20 and the source terminal 11, across the potential uniformalizing terminal 20 and the gate terminal 12, and across the potential uniformalizing terminal 20 and the drain terminal 13.

The potential uniformalizing wiring 50 thus melts by electrical stress at portions marked with dashed lines in FIG. 2.

As a result, voltages of different magnitudes can be applied to the source terminal 11, the gate terminal 12 and the drain terminal 13. This allows desired electric characteristics of the thin film transistor 10 to be measured, to conduct a characteristic inspection of the thin film transistor 10.

<C. Effect>

In the switching element according to the second preferred embodiment, the plurality of electrode terminals such as the gate terminal 12 are all connected to the potential uniformalizing terminal 20 via the potential uniformalizing wiring 50, to become equal in potential. In addition, the external input/output terminals 30 are provided so that the external input/output devices can be connected while preventing damage resulting from static electricity to the thin film transistor 10. Further, a characteristic inspection of the thin film transistor 10 can be conducted using the electrode terminals such as the gate terminal 12 even after connecting the external input/output devices.

In the characteristic inspection method of the switching element according to this preferred embodiment, the potential uniformalizing wiring 50 melts to conduct a characteristic inspection of the thin film transistor 10 after connecting the external input/output devices to the external input/output terminals 30.

Therefore, performance evaluations of the thin film transistor 10 can be conducted accurately while preventing damage resulting from static electricity which is produced when connecting the external input/output devices.

### Third Preferred Embodiment

<A. Structure>

FIG. 3 is a circuit diagram illustrating the structure of a switching element according to a third preferred embodiment of this invention.

The identical features to those in the first preferred embodiment have the same signs to omit redundant descriptions.

The switching element according to this preferred embodiment is an MIM (Metal Insulator Metal) element such as a TFD (Thin Film Diode).

An MIM element 40 has one end connected to an upper electrode terminal 15 and the other end connected to a lower electrode terminal 16. The upper electrode terminal 15 and the lower electrode terminal 16 are connected to the potential uniformalizing terminal 20 via the potential uniformalizing wiring 50.

<B. Inspection Method>

A characteristic inspection method of the switching element according to the third preferred embodiment will now be described.

First, the MIM element 40 formed on the periphery of the image display area is prepared.

Next, the potential uniformalizing wiring 50 is cut. More specifically, a voltage is applied across the potential uniformalizing terminal 20 and the upper electrode terminal 15, and across the potential uniformalizing terminal 20 and the lower electrode terminal 16. The potential uniformalizing wiring 50 thus melts by electrical stress at portions marked with dashed lines in FIG. 3.

As a result, voltages of different magnitudes can be applied to the upper electrode terminal 15 and the lower electrode terminal 16. This allows desired electric characteristics of the MIM element 40 to be measured, to conduct performance evaluations of the MIM element 40.

When using a single MIM element 40, a chip on which the MIM element 40 is formed may be fixed inside a package made of ceramic and the like.

At this time, terminals provided in the package make contact with and are electrically connected to the upper electrode terminal 15 and the lower electrode terminal 16 of the MIM element 40 inside the package.

The terminals provided in the package are then used to apply a voltage across the potential uniformalizing terminal 20 and the upper electrode terminal 15, and across the potential uniformalizing terminal 20 and the lower electrode terminal 16.

The potential uniformalizing wiring 50 thus melts by electrical stress at the portions marked with dashed lines in FIG. 3.

As a result, voltages of different magnitudes can be applied to the upper electrode terminal 15 and the lower electrode terminal 16. This allows desired electric characteristics of the MIM element 40 to be measured, to conduct performance evaluations of the MIM element 40.

When used singly, the MIM element 40 having been packaged will be protected from the external environment, and thus will be measured more safely.

<C. Effect>

In the switching element according to the third preferred embodiment having the structure described above, the plurality of electrode terminals are all equal in potential. This prevents damage resulting from static electricity and the like which is produced when handling the MIM element 40, such as when fixing into a package. Therefore, an accurate characteristic inspection of the MIM element 40 can be conducted with a high yield.

While the invention has been shown and described in detail, the foregoing description is in all aspects illustrative and not restrictive. It is therefore understood that numerous modifications and variations can be devised without departing from the scope of the invention.

What is claimed is:

1. A switching element for characteristic inspection comprising:
a plurality of electrode terminals; and
a potential uniformalizing terminal connected to said plurality of electrode terminals via wiring.

2. The switching element for characteristic inspection according to claim 1, wherein said plurality of electrode terminals and said potential uniformalizing terminal are arranged on a predetermined substrate, and connected via said wiring.

3. The switching element for characteristic inspection according to claim 2, wherein said predetermined substrate is a substrate for liquid crystal display having a switching element for image display formed in an image display area,
said switching element for characteristic inspection being arranged on the periphery of said image display area.

4. The switching element for characteristic inspection according to claim 2, wherein said predetermined substrate is a substrate for liquid crystal display,
said switching element for characteristic inspection being arranged in an image display area or on the periphery of said image display area of said substrate for liquid crystal display.

5. The switching element for characteristic inspection according to claim 1, wherein said potential uniformalizing terminal is arranged near said electrode terminals.

6. The switching element for characteristic inspection according to claim 1, wherein said wiring includes a portion narrower than the other portions of said wiring.

7. The switching element for characteristic inspection according to claim 1, wherein said wiring is made of metallic materials.

8. The switching element for characteristic inspection according to claim 1, further comprising:
an external input/output terminal connected to each of said electrode terminals.

9. The switching element for characteristic inspection according to claim 1, being a thin film transistor.

10. The switching element for characteristic inspection according to claim 1, being an MIM element.

11. A characteristic inspection method using a switching element for characteristic inspection that includes a plurality of electrode terminals and a potential uniformalizing terminal connected to said plurality of electrode terminals via wiring, said method comprising the steps of:
(a) preparing said switching element for characteristic inspection;
(b) cutting said wiring; and
(c) conducting a characteristic inspection of said switching element for characteristic inspection by using said electrode terminals after said step (b).

12. The characteristic inspection method according to claim 11, further comprising the step of:
packaging said switching element for characteristic inspection after said step (a).

13. The characteristic inspection method according to claim 11, wherein said step (b) of cutting said wiring includes the step of:
(d) applying a voltage across said electrode terminals and said potential uniformalizing terminal to melt said wiring.

14. A characteristic inspection method using a switching element for characteristic inspection that includes a plurality of electrode terminals, a potential uniformalizing terminal connected to said plurality of electrode terminals via wiring, and an external input/output terminal connected to each of said electrode terminals, said method comprising the steps of:
(a) preparing said switching element for characteristic inspection;
(b) connecting an external input/output device to said external input/output terminal;
(c) cutting said wiring after said step (b); and
(d) conducting a characteristic inspection of said switching element for characteristic inspection by using said electrode terminals after said step (c).

15. The characteristic inspection method according to claim 14, further comprising the step of:
packaging said switching element for characteristic inspection after said step (a).

16. The characteristic inspection method according to claim 14, wherein said step (c) of cutting said wiring includes the step of:
(e) applying a voltage across said electrode terminals and said potential uniformalizing terminal to melt said wiring.
